(19) United States
(12) Patent Application Publication
(10) Pub. No.: US 2026/0107796 A1
(43) Pub. Date: Apr. 16, 2026

(54) SEMICONDUCTOR PACKAGE

(71) Applicant: SAMSUNG ELECTRO-MECHANICS CO., LTD., Suwon-si (KR)

(72) Inventors: Seung Eun LEE, Suwon-si (KR); Sung Youl CHOI, Suwon-si (KR)

(73) Assignee: SAMSUNG ELECTRO-MECHANICS CO., LTD., Suwon-si (KR)

(21) Appl. No.: 19/214,734

(22) Filed: May 21, 2025

(30) Foreign Application Priority Data
Oct. 16, 2024 (KR) 10-2024-0141047

(51) Int. Cl. H01L 23/498; H01L 23/14; H01L 23/31; H01L 25/04

(52) U.S. Cl. CPC H10W 70/635; H10W 74/129; H10W 90/00; H10W 90/401; H10W 70/695; H10W 72/823; H10W 90/20; H10W 90/24

(57) ABSTRACT

A semiconductor package includes a redistribution layer, a first substrate disposed on the redistribution layer and having a first cavity, a first semiconductor chip in the first cavity and having a first connection pad, a first encapsulant covering the first semiconductor chip and filling the first cavity, a second substrate disposed on the first substrate and having a second cavity, a second semiconductor chip in the second cavity and having a second connection pad, a second encapsulant covering the second semiconductor chip and filling the second cavity, a first connection via penetrating through the first encapsulant, directly connected to the first connection pad, and connecting the first connection pad to the redistribution layer, and a second connection via penetrating through the first substrate and the first and second encapsulants, directly connected to the second connection pad, and connecting the second connection pad to the redistribution layer.

### CROSS-REFERENCE TO RELATED APPLICATION(S)

This application claims benefit of priority to Korean Patent Application No. 10-2024-0141047 filed on Oct. 16, 2024 in the Korean Intellectual Property Office, the disclosure of which is incorporated herein by reference in its entirety.

### TECHNICAL FIELD

The present disclosure relates to a semiconductor package, for example, a stack memory package.

In order to enhance the AI performance of mobile products, high-performance stack memory packages have been required, and various vertical interconnection technologies, such as technologies using metal wires, have been developed for electrical connection of such stack memory packages. However, there is a limit to forming a thin metal wire to be tall and long, and there is also a possibility that the metal wire may be damaged during molding after forming the metal wire.

### SUMMARY

An aspect of the present disclosure is to provide a semiconductor package in which stably stacked semiconductor chips are vertically interconnected.

Another aspect of the present disclosure is to provide a semiconductor package in which a semiconductor chip is prevented from being warped during molding of the semiconductor chip.

According to an aspect of the present disclosure, a semiconductor package includes: a redistribution layer; a first substrate disposed on the redistribution layer and having a first cavity; a first semiconductor chip at least partially disposed in the first cavity and having a first connection pad disposed to face the redistribution layer; a first encapsulant disposed between the redistribution layer and the first substrate, covering at least a portion of the first semiconductor chip, and filling at least a portion of the first cavity; a second substrate disposed on the first substrate and having a second cavity; a second semiconductor chip at least partially disposed in the second cavity and having a second connection pad disposed to face the first substrate; a second encapsulant disposed between the first and second substrates, covering at least a portion of the second semiconductor chip, and filling at least a portion of the second cavity; a first connection via penetrating through the first encapsulant, directly connected to the first connection pad, and connecting the first connection pad to the redistribution layer; and a second connection via penetrating through the first substrate and the first and second encapsulants, directly connected to the second connection pad, and connecting the second connection pad to the redistribution layer.

According to another aspect of the present disclosure, a semiconductor package includes: a redistribution layer; a plurality of encapsulants and a plurality of substrates alternately arranged on the redistribution layer; a plurality of memory dies at least partially disposed in cavities penetrating each of the plurality of substrates and at least partially covered by the plurality of encapsulants, respectively; and a plurality of connection vias penetrating at least one of the plurality of encapsulants and the plurality of substrates and solderlessly connected to the plurality of memory dies, respectively, and connecting each of the plurality of memory dies to the redistribution layer.

According to still another aspect of the present disclosure, a semiconductor package includes a redistribution layer and a stack of layer structures disposed on the redistribution layer. Each respective layer structure in the stack of layer structures includes a corresponding substrate, a corresponding cavity, a corresponding semiconductor chip and a corresponding encapsulant. The corresponding substrate has (i) a corresponding first surface facing the redistribution layer and (ii) a corresponding second surface opposite to the corresponding first surface. The corresponding cavity is disposed in the corresponding substrate and penetrates at least the corresponding first surface of the corresponding substrate. The corresponding semiconductor chip is at least partially disposed in the corresponding cavity and has (i) a corresponding front surface facing the redistribution layer and (ii) a corresponding connection pad facing the redistribution layer and electrically connected to the redistribution layer. The corresponding encapsulant has (i) a first portion filling a portion of the corresponding cavity and (ii) a second portion covering the corresponding front surface of the corresponding semiconductor chip, the corresponding first surface of the corresponding substrate, and one of the redistribution layer and a second surface of a substrate of an adjacent layer structure in the stack of layer structures.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a semiconductor package;

FIG. 4 is a process diagram schematically illustrating an example of manufacturing the semiconductor package of FIG. 3; and

FIG. 5 is a cross-sectional diagram schematically illustrating another example of a semiconductor package.

### DETAILED DESCRIPTION

Hereinafter, the present disclosure will be described with reference to the accompanying drawings. The shapes and sizes of elements in the drawings may be exaggerated or reduced for a clearer explanation.

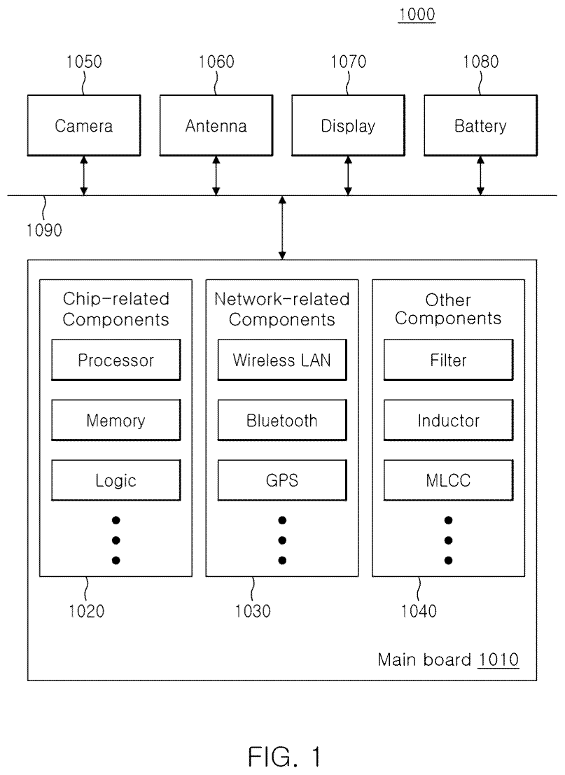

Referring to FIG. 1, an electronic device 1000 accommodates a main board 1010. A chip-related component 1020, a network-related component 1030, and other components 1040 are physically and/or electrically connected to the main board 1010. These components are combined with other electronic components to be described below to form various signal lines 1090.

The chip-related component 1020 includes memory chips, such as volatile memories (e.g., DRAM), nonvolatile memory (e.g., ROM), and flash memories; application processor chips, such as central processors (e.g., CPUs), graphics processors (e.g., GPUs), digital signal processors, encryption processors, microprocessors, and microcontrollers; logic chips, such as analog-to-digital converters (ADCs), and application-specific integrated circuits (ASICs), but is not limited thereto and may include other types of chip-related electronic components as well. In addition, these chip-related components 1020 may be combined with each other. The chip-related component 1020 may be in the form of a package including the aforementioned chip or electronic component.

The network related component 1030 may include Wi-Fi (IEEE 802.11 family, etc.), WiMAX (IEEE 802.16 family, etc.), IEEE 802.20, long term evolution (LTE), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but is not limited to and may include any of other wireless or wired standards or protocols. In addition, the network-related component 1030 and the chip-related component 1020 may be combined with each other.

The other components 1040 include high-frequency inductors, ferrite inductors, power inductors, ferrite beads, low temperature co-firing ceramics (LTCCs), electro-magnetic interference (EMI) filters, multi-layer ceramic condensers (MLCCs), and the like. However, the other components 1040 are not limited thereto and may include passive elements in the form of chip components used for various other purposes. In addition, the other components 1040 may be combined with the chip-related component 1020 and/or the network-related component 1030.

Depending on the type of electronic device 1000, the electronic device 1000 may include other electronic components that may or may not be physically and/or electrically connected to the main board 1010. The other electronic components may include, for example, a camera 1050, an antenna 1060, a display 1070, and a battery 1080. However, the electronic components are not limited thereto and may include audio codecs, video codecs, power amplifiers, compasses, accelerometers, gyroscopes, speakers, mass storage devices (e.g., hard disk drives), compact disks (CDs), digital versatile disks (DVDs), etc. In addition, other electronic components used for various purposes may be included depending on the type of the electronic device 1000.

The electronic device 1000 may include smartphones, personal digital assistants (PDAs), digital video cameras, digital still cameras, network systems, computers, monitors, tablets, laptops, netbooks, televisions, video game machines, smart watches, automotives, and the like. However, the electronic device 1000 is not limited thereto, and may be any other electronic device that processes data, such as a server or the like, in addition thereto.

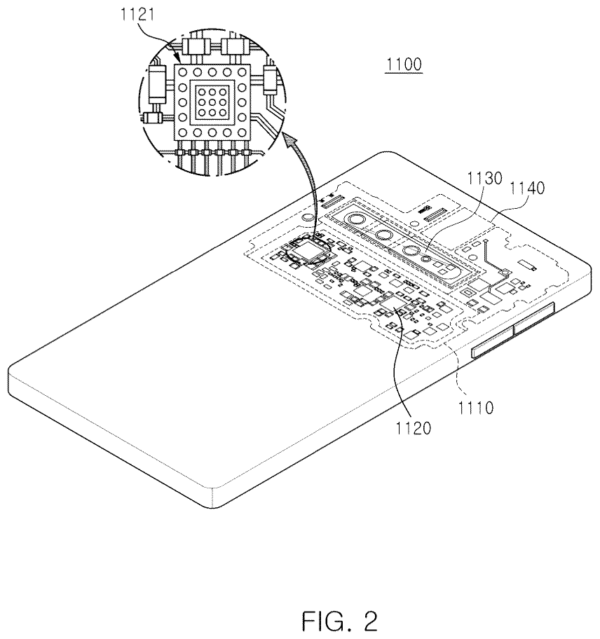

FIG. 2 is a perspective view schematically illustrating an example of an electronic device.

Referring to FIG. 2, the electronic device may be, for example, a smartphone 1100. A motherboard 1110 is accommodated inside the smartphone 1100, and various components 1120 are physically and/or electrically connected to the motherboard 1110. In addition, other components that may or may not be physically and/or electrically connected to the motherboard 1110, such as a camera module 1130 and/or a speaker 1140, are accommodated in the smartphone 1100. Some of the components 1120 may be the aforementioned chip-related components, for example, a component package 1121, but is not limited thereto.

Referring to the drawing, the electronic device may be, for example, a smartphone 1100. A motherboard 1110 is accommodated inside the smartphone 1100, and various components 1120 are physically and/or electrically connected to the motherboard 1110. In addition, other components, such as a camera module 1130 and/or a speaker 1140, which may or may not be physically and/or electrically connected to the motherboard 1110, are accommodated inside. Some of the components 1120 may be the chip-related components described above, and may be, for example, a semiconductor package 1121, but are not limited thereto.

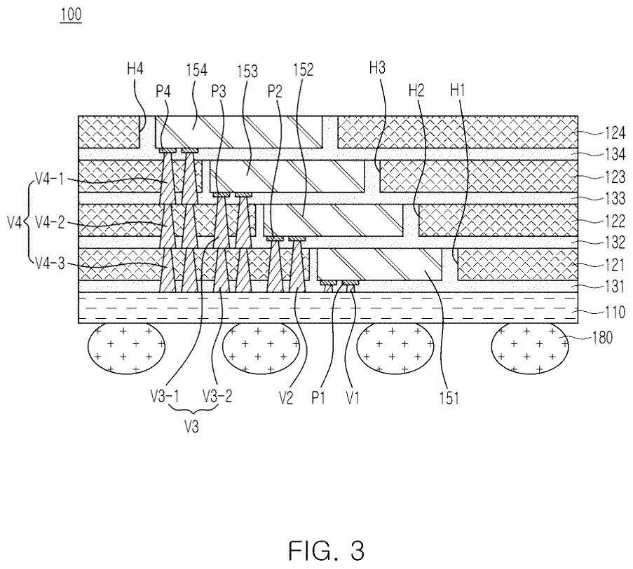

FIG. 3 is a cross-sectional view schematically illustrating an example of a semiconductor package.

Referring to FIG. 3, a semiconductor package 100 may include a redistribution layer 110, a plurality of encapsulants 131, 132, 133, and 134 and a plurality of substrates 121, 122, 123, and 124 alternately arranged on the redistribution layer 110, a plurality of semiconductor chips 151, 152, 153, and 154 at least partially disposed in cavities H1, H2, H3, and H4 penetrating each of the plurality of substrates 121, 122, 123, and 124 and at least partially covered respectively by the plurality of encapsulants 131, 132, 133, and 134, and a plurality of connection vias V1, V2, V3, and V4 solderlessly connected respectively to the plurality of semiconductor chips 151, 152, 153, and 154 through one or more of the plurality of encapsulants 131, 132, 133, and 134 and the plurality of substrates 121, 122, 123, and 124 and connecting each of the plurality of semiconductor chips 151, 152, 153, and 154 to the redistribution layer 110.

More specifically, the semiconductor package 100 may include the redistribution layer 110, a first substrate 121 disposed on the redistribution layer 110 and having a first cavity H1, a first semiconductor chip 151 at least partially disposed in the first cavity H1 and having a first connection pad P1 disposed to face the redistribution layer 110, a first encapsulant 131 disposed between the redistribution layer 110 and the first substrate 121, covering at least a portion of the first semiconductor chip 151, and filling at least a portion of the first cavity H1, a second substrate 122 disposed on the first substrate 121 and having a second cavity H2, a second semiconductor chip 152 at least partially disposed in the second cavity H2 and having a second connection pad P2 and disposed to face the first substrate 121, a second encapsulant 132 disposed between the first and second substrates 121 and 122, covering at least a portion of the second semiconductor chip 152, and filling at least a portion of the second cavity H2, a first connection via V1 directly connected to the first connection pad P1 through the first encapsulant 131 and connecting the first connection pad P1 to the redistribution layer 110, and a second connection via V2 directly connected to the second connection pad P2 through the first substrate 121 and the first and second encapsulants 131 and 132 and connecting the second connection pad P2 to the redistribution layer 110.

In addition, the semiconductor package 100 may further include a third substrate 123 disposed on the second substrate 122 and having a third cavity H3; a third semiconductor chip 153 at least partially disposed in the third cavity H3 and having a third connection pad P3 disposed to face the second substrate 122; a third encapsulant 133 disposed between the second and third substrates 122 and 123, covering at least a portion of the third semiconductor chip 153, and filling at least a portion of the third cavity H3; a third connection via V3 directly connected to the third connection pad P3 through the first and second substrates 121 and 122 and the first to third encapsulants 131, 132, and 133 and connecting the third connection pad P3 to the redistribution layer 110; a fourth substrate 124 disposed on the third substrate 123 and having a cavity H4, a fourth semiconductor chip 154 at least partially disposed in the fourth cavity H4 and having a fourth connection pad P4 disposed to face the third substrate 123, a fourth encapsulant 134 disposed between the third and fourth substrates 123 and 124, covering at least a portion of the fourth semiconductor chip 154, and filling at least a portion of the fourth cavity H4, a fourth connection via V4 directly connected to the fourth connection pad P4 through the first to third substrates 121, 122, and 123 and the first to fourth encapsulants 131, 132, 133, and 134 and connecting the fourth connection pad P4 to the redistribution layer 110, and a plurality of electrical connection metals 180 disposed on a surface of the redistribution layer 110 opposite to a surface of the redistribution layer 110 on which the first substrate 121 is disposed and each connected to the redistribution layer 110.

In this manner, in the semiconductor package 100, the cavities H1, H2, H3, and H4 are respectively formed in the substrates 121, 122, 123, and 124, the semiconductor chips 151, 152, 153, and 154 are respectively disposed in the cavities H1, H2, H3, and H4, the semiconductor chips 151, 152, 153, and 154 are covered with the encapsulants 131, 132, 133, and 134, and the semiconductor chips 151, 152, 153, and 154 may be connected to the redistribution layer 110 using the connection vias V1, V2, V3, and V4 penetrating at least one of the substrates 121, 122, 123, and 124 and the encapsulants 131, 132, 133, and 134. For example, the stably stacked semiconductor chips 151, 152, 153, and 154 may be vertically connected to each other through the connection vias V1, V2, V3, and V4 without thin metal posts or metal wires. In addition, since the substrates 121, 122, 123, and 124 in which cavities H1, H2, H3, and H4 are formed surrounding semiconductor chips 151, 152, 153, and 154, respectively, when the semiconductor chips 151, 152, 153, and 154 are covered with the encapsulants 131, 132, 133, and 134, respectively, positional misalignment of the respective semiconductor chips 151, 152, 153, and 154 may be prevented. In addition, since interconnection is made through the connection vias V1, V2, V3, and V4, solder bumps may be unnecessary. For example, the vertical interconnection structure may be a solderless structure.

Meanwhile, each of the first to fourth semiconductor chips 151, 152, 153, and 154 may be a memory die. For example, the semiconductor package 100 may be a stack memory package. For example, each memory die may include a wide I/O memory, and thus, by processing data in parallel using more input/output (I/O) pins, the bandwidth may be significantly improved and power consumption may be reduced. In addition, it may play an important role in improving performance in small devices, such as system on chip (SoC) of mobile devices. For example, it may be used to increase memory bandwidth in a mobile environment requiring high performance and low power in a narrow space, and may have a 3D stack structure.

Meanwhile, the first to fourth substrates 121, 122, 123, and 124 may each be a typical organic substrate, and may include, for example, a copper clad laminate (CCL) or an unclad CCL. Accordingly, process warpage may be effectively controlled. In addition, the first to fourth connection vias V1, V2, V3, and V4 may be formed more easily. In addition, when covering the semiconductor chips 151, 152, 153, and 154 with the encapsulants 131, 132, 133, and 134, respectively, positional misalignment of each of the semiconductor chips 151, 152, 153, and 154 may be prevented.

Meanwhile, the first to fourth cavities H1, H2, H3, and H4 may each be a through-cavity. For example, the first to fourth cavities H1, H2, H3, and H4 may penetrate between the opposing one surface and the other surface, for example, between an upper surface and a lower surface, of each of the first to fourth substrates 121, 122, 123, and 124. Accordingly, the first to fourth semiconductor chips 151, 152, 153, and 154 may be disposed more easily in the first to fourth cavities H1, H2, H3, and H4, and the difficulty of an embedding process may be reduced.

Meanwhile, a surface of the first substrate 121 in contact with the second encapsulant 132 may be substantially coplanar with a surface of the first semiconductor chip 151 in contact with the second encapsulant 132. In addition, a surface of the second substrate 122 in contact with the third encapsulant 133 may be substantially coplanar with a surface of the second semiconductor chip 152 in contact with the third encapsulant 133. In addition, a surface of the third substrate 123 in contact with the fourth encapsulant 134 may be substantially coplanar with a surface of the third semiconductor chip 153 in contact with the fourth encapsulant 134. In addition, a surface of the fourth substrate 124 opposite to a surface facing the third substrate 123 may be substantially coplanar with a surface of the fourth semiconductor chip 154 opposite to a surface facing the third semiconductor chip 153. For example, in a stacking process using a carrier as described below, a flat base surface may be provided in each operation, and thus, the stacking process may be performed more easily. In addition, it is possible to more effectively prevent misalignment of semiconductor chips 151, 152, 153, and 154 in the embedding process.

Meanwhile, the first and second connection vias V1 and V2 may be tapered so that a width of an end portion thereof connected to the redistribution layer 110 in a cross-section is wider than a width of an end portion thereof connected to the first and second connection pads P1 and P2. For example, the first and second connection vias V1 and V2 may be formed by processing a via hole from the side in which the redistribution layer 110 is disposed to each of the connection pad P1 and P2 and then filling the via hole by plating. Therefore, a separate solder bump may be unnecessary. For example, the vertical interconnection structure may be a solderless structure.

Meanwhile, the third connection via V3 may include a 3-1 connection via V3-1 directly connected to the third connection pad P3 through the second substrate 122 and the second and third encapsulants 132 and 133 and a 3-2 connection via V3-2 connecting the 3-1 connection via V3-1 to the redistribution layer 110 through the first substrate 121 and the first encapsulant 131. In addition, the fourth connection via V4 may include a 4-1 connection via V4-1 directly connected to the fourth connection pad P4 through the third substrate 123 and the third and fourth encapsulants 133 and 134, a 4-2 connection via V4-2 connected to the 4-1 connection via V4-1 through the second substrate 122 and the second encapsulant 132, and a 4-3 connection via V4-3 connecting the 4-2 connection via V4-2 to the redistribution layer 110 through the first substrate 121 and the first encapsulant 131. For example, the third and fourth connection vias V3 and V4 may each be a stacked via structure vertically connected without a land. Therefore, via connection may be possible more stably and with a finer pitch.

Meanwhile, in the cross-section, a width of an end portion of the 3-1 connection via V3-1 connected to the 3-2 connection via V3-2 may be wider than a width of an end portion of the 3-2 connection via V3-2 connected to the 3-1 connection via V3-1. In addition, in the cross-section, a width of an end portion of the 4-1 connection via V4-1 connected to the 4-2 connection via V4-2 may be wider than a width of an end portion of the 4-2 connection via V4-2 connected to the 4-1 connection via V4-1, and a width of an end portion of the 4-2 connection via V4-2 connected to the 4-3 connection via V4-3 may be wider than a width of an end portion of the 4-3 connection via V4-3 connected to the 4-2 connection via V4-2. For example, the 3-1 and 3-2 connection vias V3-1 and V3-2 and the 4-1, 4-2, and 4-3 connection vias V4-1, V4-2, and V4-3 may be formed by processing via holes from the side in which the redistribution layer 110 is disposed to the opposite side and then filling the via holes by plating, and in particular, may be formed to be separated during the stacking process. Therefore, a separate solder bump may be unnecessary. For example, the vertical interconnection structure may be a solderless structure. In addition, therefore, via connection may be possible more stably and with a finer pitch.

Hereinafter, the components of the semiconductor package 100 will be described in more detail with reference to the drawings.

The redistribution layer 110 may perform a redistribution function for a plurality of semiconductor chips 151, 152, 153, and 154. For example, the redistribution layer 110 may perform a redistribution function for fan-out. In this respect, the redistribution layer 110 may include a plurality of insulating layers, a plurality of conductive pattern layers respectively disposed within the plurality of insulating layers, and a plurality of conductive via layers respectively disposed within the plurality of insulating layers and connected to at least one of the plurality of conductive pattern layers. One of the plurality of conductive pattern layers may include a conductive pattern connected to each of the plurality of connection vias V1, V2, V3, and V4. Another of the plurality of conductive pattern layers may include a conductive pattern connected to each of a plurality of electrical connection metals 180. The plurality of conductive via layers may provide electrical connection paths within the redistribution layer 110.

The plurality of insulating layers may each include an organic insulating material. Here, the organic insulating material may include a thermosetting resin, such as an epoxy resin, a thermoplastic resin, such as polyimide, or a material including an inorganic filler and/or an organic filler together with a resin. For example, here, the organic insulating material may be a non-photosensitive insulating material, such as Ajinomoto build-up film (ABF), but is not limited thereto, and other polymer materials may be used. In addition, the organic insulating material may include a photosensitive insulating material, such as photo imageable dielectric (PID). The plurality of insulating layers may include substantially the same organic insulating material and may be integrated with each other after curing so that the boundaries therebetween are not apparent.

The plurality of conductive pattern layers may each include a metal. The metal may include copper (Cu), aluminum (Al), silver (Ag), tin (Sn), gold (Au), nickel (Ni), lead (Pb), titanium (Ti), and/or alloys thereof. The plurality of conductive pattern layers may each perform various functions according to the design. For example, they may include a signal pattern, a power pattern, a ground pattern, etc. These patterns may each have various shapes, such as a line, a plane, a pad, a land, etc. Each of the plurality of conductive pattern layers may include a sputter layer and/or an electroless plating layer as a seed layer and may include an electrolytic plating layer as a plating layer formed on the seed layer. The number of layers of the plurality of conductive pattern layers is not particularly limited and may be formed as needed.

Each of the plurality of conductive via layers may include a metal. The metal may include copper (Cu), aluminum (Al), silver (Ag), tin (Sn), gold (Au), nickel (Ni), lead (Pb), titanium (Ti), and/or alloys thereof. Each of the plurality of conductive via layers may include a filled via filling a via hole, but may also include a conformal via disposed on a wall surface of the via hole. Each of the plurality of conductive via layers may perform various functions according to a design. For example, each of the plurality of conductive via layers may include a ground via, a power via, a signal via, etc. The plurality of conductive via layers may each include a sputter layer and/or an electroless plating layer as a seed layer and may include an electrolytic plating layer as a plating layer formed on the seed layer. The number of layers of the plurality of conductive via layers is not particularly limited and may be formed as needed.

The plurality of substrates 121, 122, 123, and 124 may each include an organic insulating material or an inorganic insulating material. Here, the organic insulating material may include a thermosetting resin, such as an epoxy resin, a thermoplastic resin, such as polyimide, or a material including an inorganic filler, an organic filler, and/or glass fiber together with a resin. For example, the organic insulating material may include an insulating material, such as prepreg (PPG), copper clad laminate (CCL), etc., but is not limited thereto, and other polymer materials may be used in addition thereto. The inorganic insulating material may include, but is not limited to, ceramic, glass, etc. The plurality of cavities H1, H2, H3, and H4 may respectively penetrate at least a portion of the plurality of substrates 121, 122, 123, and 124 and may preferably be through-cavities as described above, but are not limited thereto.

The plurality of encapsulants 131, 132, 133, and 134 may include an organic insulating material. Here, the organic insulating material may include a thermosetting resin, such as an epoxy resin, a thermoplastic resin, such as polyimide, or a material including an inorganic filler and/or an organic filler together with a resin. For example, the organic insulating material may include, but is not limited to, ABF, EMC, and the like, and other polymeric materials may also be used. The plurality of encapsulants 131, 132, 133, and 134 may include substantially the same organic insulating material as each other and may be integrated with each other after curing so that the boundaries therebetween are not apparent.

The plurality of semiconductor chips 151, 152, 153, and 154 may each include an integrated circuit (IC) die in which hundreds to millions of elements are integrated into a single chip. At this time, the integrated circuit may be a memory die, such as, a volatile memory (e.g., DRAM), a nonvolatile memory (e.g., ROM), a flash memory, a high bandwidth memory (HBM), etc. and may preferably include a wide I/O memory as described above, but is not limited thereto.

Each of the plurality of connection pads P1, P2, P3, and P4 may include a metal. The metal may include copper (Cu), aluminum (Al), silver (Ag), tin (Sn), gold (Au), nickel (Ni), lead (Pb), titanium (Ti), and/or alloys thereof. The plurality of connection pads P1, P2, P3, and P4 may be arranged respectively to protrude from active surfaces of the plurality of semiconductor chips 151, 152, 153, and 154, but are not limited thereto, and may be arranged to be embedded based on the active surfaces of the plurality of semiconductor chips 151, 152, 153, and 154. If necessary, the plurality of connection pads P1, P2, P3, and P4 may each include a conductive bump, and the conductive bump may be a typical metal bump other than a solder bump. For example, the metal bump may be formed on an aluminum pad and may include, but is not limited to, a seed layer including sputtered titanium/copper or chemical copper and a plating layer including cathode copper. The plurality of connection pads P1, P2, P3, and P4 may each be plural.

The plurality of connection vias V1, V2, V3, and V4 may each include a metal. The metal may include copper (Cu), aluminum (Al), silver (Ag), tin (Sn), gold (Au), nickel (Ni), lead (Pb), titanium (Ti), and/or alloys thereof. The plurality of connection vias V1, V2, V3, and V4 may each include a filled via filling a via hole, but may also include a conformal via disposed on a wall surface of the via hole. The plurality of connection vias V1, V2, V3, and V4 may each perform various functions according to a design. For example, it may include ground vias, power vias, signal vias, etc. The plurality of connection vias V1, V2, V3, and V4 may each include a sputter layer and/or an electroless plating layer as a seed layer and may include an electrolytic plating layer as a plating layer formed on the seed layer. The plurality of connection vias V1, V2, V3, and V4 may each be formed in plural. Meanwhile, the shape of the plurality of connection vias V1, V2, V3, and V4 does not necessarily have to be a tapered shape and may have a cylindrical shape with a side surface approximately vertical, if necessary.

The plurality of electrical connection metals 180 may each be formed of a low-melting point metal, for example, solder, such as tin (Sn)-aluminum (Al)-copper (Cu), but this is only an example, and the material is not particularly limited thereto. The plurality of electrical connection metals 180 may each be a ball, a pin, etc. The plurality of electrical connection metals 180 may be formed as a multiple layers or a single layer. When formed as multilayers, they may include copper pillars and solder, and when formed as a single layer, they may include tin-silver solder, but are not limited thereto. The plurality of electrical connection metals 180 may be used to mount the semiconductor package 100 on another substrate or another package. The number of the plurality of electrical connection metals 180 is not particularly limited and may be formed as needed.

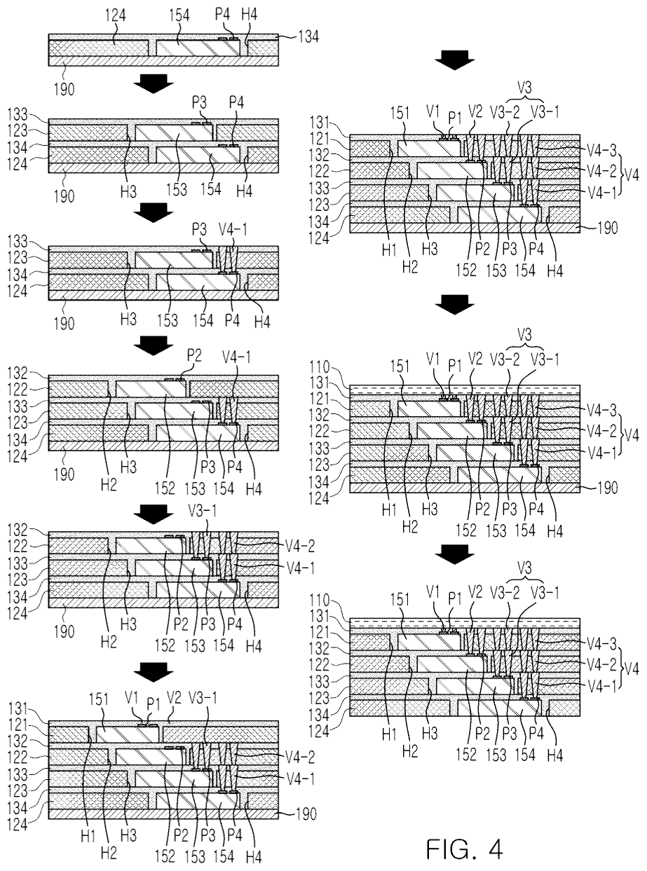

FIG. 4 is a process diagram schematically illustrating an example of manufacturing the semiconductor package of FIG. 3.

Referring to FIG. 4, first, the fourth substrate 124 in which the fourth cavity H4 is formed is attached to a carrier 190, and the fourth semiconductor chip 154 is disposed in the fourth cavity H4, and then the fourth substrate 124 and the fourth semiconductor chip 154 may be covered with the fourth encapsulant 134.

Next, the third substrate 123 having the third cavity H3 is attached on the fourth encapsulant 134, the third semiconductor chip 153 is disposed in the third cavity H3, and then the third substrate 123 and the third semiconductor chip 153 may be covered with the third encapsulant 133.

Next, a via hole penetrating through the third substrate 123 and the third and fourth encapsulants 133 and 134 up to the fourth connection pad P4 of the fourth semiconductor chip 154 may be processed using a laser drill or a mechanical drill, and then filled with plating to form the 4-1 connection via V4-1.

Next, the second substrate 122 having the second cavity H2 is attached on the third encapsulant 133, the second semiconductor chip 152 is disposed in the second cavity H2, and then the second substrate 122 and the second semiconductor chip 152 may be covered with the second encapsulant 132.

Next, a via hole penetrating through the second substrate 122 and the second and third encapsulants 132 and 133 up to the third connection pad P3 of the third semiconductor chip 153 may be processed using a laser drill or a mechanical drill, and then filled with plating to form the 3-1 connection via V3-1. In addition, a via hole penetrating through the second substrate 122 and the second and third encapsulants 132 and 133 up to the 4-1 connection via V4-1 may be processed using a laser drill or a mechanical drill, and then filled with plating to form the 4-2 connection via V4-2.

Next, a first substrate 121 having the first cavity H1 is attached on the second encapsulant 132, the first semiconductor chip 151 may be disposed in the first cavity H1, and then the first substrate 121 and the first semiconductor chip 151 may be covered with the first encapsulant 131.

Next, a via hole penetrating through the first encapsulant 131 up to the first connection pad P1 of the first semiconductor chip 151 may be processed using a laser drill or a mechanical drill, and then filled with plating to form the first connection via V1. In addition, a via hole penetrating through the first substrate 121 and the first and second encapsulants 131 and 132 up to the second connection pad P2 of the second semiconductor chip 152 may be processed using a laser drill or a mechanical drill, and then filled with plating to form the second connection via V2. In addition, a via hole penetrating through the first substrate 121 and the first and second encapsulants 131 and 132 up to the 3-1 connection via V3-1 may be processed using a laser drill or a mechanical drill, and then filled with plating to form the 3-2 connection via V3-2. In addition, a via hole penetrating through the first substrate 121 and the first and second encapsulants 131 and 132 up to the 4-2 connection via V4-2 may be processed using a laser drill or a mechanical drill, and then filled with plating to form the 4-3 connection via V4-3. The 3-1 and 3-2 connection vias V3-1 and V3-2 may be vertically connected to form the third connection via V3. The 4-1, 4-2, and 4-3 connection vias V4-1, V4-2, and V4-3 may be vertically connected to form the fourth connection via V4.

Next, the redistribution layer 110 may be formed on the first encapsulant 131. The redistribution layer 110 may be formed by sequentially forming a conductive pattern layer, an insulating layer, and a conductive via layer using, for example, a build-up process. The build-up process may include forming an insulating layer through coating or lamination, forming a via hole through photolithography or laser processing, forming a conductive pattern layer and a conductive via layer through a plating process using a resist, etc.

Next, the semiconductor package manufactured from the carrier 190 may be separated, and a plurality of electrical connection metals may be formed on the redistribution layer 110 as needed.

Other contents may be substantially the same those of the semiconductor package 100 described above.

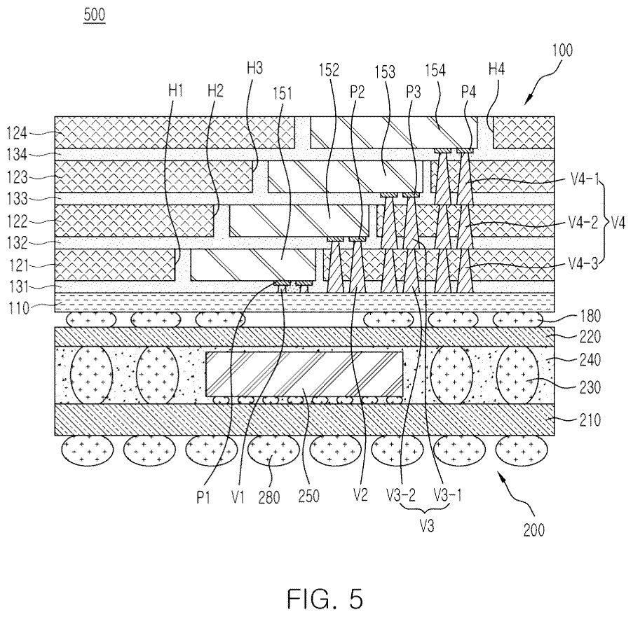

FIG. 5 is a cross-sectional view schematically illustrating another example of a semiconductor package.

Referring to FIG. 5, a semiconductor package 500 may have a package-on-package structure. For example, it may have a structure in which the semiconductor package 100 described above is stacked on a chip package 200. For example, the redistribution layer 110 of the semiconductor package 100 described above may be disposed on the chip package 200 and connected to the chip package 200 through a plurality of electrical connection metals 180. The chip package 200 may include a semiconductor chip 250, and the semiconductor chip 250 may include a system on chip (SoC). For example, the semiconductor package 500 may be a stack structure of the chip package 200 including an SoC and the semiconductor package 100 including a 3D stacked wide I/O memory.

Hereinafter, components of the semiconductor package 500 will be described in more detail with reference to the drawings.

The chip package 200 may include a front redistribution layer 210 and a backside redistribution layer 220, a semiconductor chip 250 mounted on the front redistribution layer 210, a bump 230 connecting the front redistribution layer 210 and the backside redistribution layer 220, a molding material 240 disposed between the front redistribution layer 210 and the backside redistribution layer 220 to mold the semiconductor chip 250 and the bump 230, and a plurality of electrical connection metals 280 each disposed on the side of the front redistribution layer 210 opposite to the side on which the semiconductor chip 250 is mounted. However, the structure of the chip package 200 is not limited thereto, and various types of package structures including the semiconductor chip 250 may be applied to the chip package 200.

The front redistribution layer 210 and the backside redistribution layer 220 may each include a plurality of insulating layers, a plurality of conductive pattern layers, and a plurality of conductive via layers. The specific details of the plurality of insulating layers, the plurality of conductive pattern layers, and the plurality of conductive via layers may be substantially the same as those described in the redistribution layer 110 of the semiconductor package 100 described above.

The bump 230 may include various types of conductive bumps. For example, a solder bump, or a general metal bump other than the solder bump, or a hybrid bump in which a metal is disposed in solder, etc. may be applied.

The molding material 240 may include an organic insulating material. Here, the organic insulating material may include a thermosetting resin, such as an epoxy resin, a thermoplastic resin, such as polyimide, or a material including an inorganic filler and/or an organic filler together with a resin. For example, here, the organic insulating material may include, but is not limited to, ABF, EMC, etc., and other polymer materials may be used.

The semiconductor chip 250 may include an integrated circuit (IC) die in which hundreds to millions of elements are integrated into a single chip. At this time, the integrated circuit may include, but is not limited to, an SoC.

The plurality of electrical connection metals 280 may each be formed of a low-melting point metal, for example, solder, such as tin (Sn)-aluminum (Al)-copper (Cu), but this is only an example and the material is not particularly limited thereto. The plurality of electrical connection metals 280 may each be a ball, a pin, etc. The plurality of electrical connection metals 280 may each be formed of multiple layers or a single layer. When formed as multiple layers, it may include copper pillars and solder, and when formed as a single layer, it may include tin-silver solder, but is not limited thereto. A plurality of electrical connection metals 280 may be used to mount the semiconductor package 500 on another substrate, such as a main board, etc. The number of the plurality of electrical connection metals 280 is not particularly limited and may be formed as needed.

Other details may be substantially the same as those described in the semiconductor package 100 and the manufacturing method thereof.

As one of the effects of the present disclosure, the semiconductor package in which stably stacked semiconductor chips are vertically interconnected may be provided.

As another of the effects of the present disclosure, the semiconductor package in which misalignment of a semiconductor chip during molding of the semiconductor chip is prevented may be provided.

In the present disclosure, thickness, width, length, depth, line width, spacing, pitch, and the like may be measured using a scanning microscope or an optical microscope based on a cross-section obtained by polishing or cutting a semiconductor package. The cut section may be a vertical cross-section or a horizontal cross-section, and each value may be measured based on the required cut section. At this time, if the value is not constant, the value may be determined as an average value of the values measured from five arbitrary points. A width of an end portion of a via may be measured from a cross-section cut along a central axis of the via.

In the present disclosure, the expression “covering” may include not only covering entirely but also covering at least portion, and may also include covering indirectly as well as covering directly. In addition, the expression “filling” may include not only completely filling but also at least partially filling, and may also include approximately filling. For example, this may include cases in which some air gaps or voids exist.

In the present disclosure, determination may be made to include process errors, position deviations, errors during measurement, and the like that occur during a manufacturing process. For example, substantially the same in terms of line width, spacing, thickness, height, etc., may include not only cases in which they are numerically completely the same, but also cases in which they have approximately similar numerical values. Furthermore, substantially having a certain shape may include cases in which they have approximately that shape, as well as cases in which they have exactly that shape. In addition, substantially being coplanar may include not only presence completely on the same plane, but also presence approximately on the same plane.

In the present disclosure, the same material may refer to not only the same material but also the same type of material. Accordingly, the composition of the materials may be substantially the same, but their specific composition ratios may be slightly different.

In the present disclosure, a cross-section may refer to a cross-sectional shape when an object is cut vertically or a cross-sectional shape when an object is viewed from a side view. In addition, “on a plane” may refer to a planar shape when an object is cut horizontally or a planar shape when an object is viewed from a top-view or bottom-view.

In the present disclosure, a lower side, a lower portion, a lower surface, and the like are used to refer to a downward direction based on a cross-section of a drawing for the sake of convenience, and an upper side, an upper portion, an upper surface, and the like are used to mean the opposite direction. In addition, the terms a side portion, a side surface, etc. are used to refer to directions perpendicular to upper and lower surfaces. However, this defines directions for convenience of description, and the scope of the claims is not particularly limited by the descriptions of the directions, and the concept of top/bottom may change at any time.

In the present disclosure, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” In addition, it may be understood that when an element is referred to with “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The expression “an exemplary embodiment or one example” used in the present disclosure does not refer to identical examples and is provided to stress different unique features between each of the examples. However, examples provided in the following description are not excluded from being associated with features of other examples and implemented thereafter. For example, even if matters described in a specific example are not described in a different example thereto, the matters may be understood as being related to the other example, unless otherwise mentioned in descriptions thereof.

The terms used in the present inventive concept are used to simply describe an example and are not intended to limit the present inventive concept. A singular term includes a plural form unless otherwise indicated.

What is claimed is:

1. A semiconductor package comprising:
a redistribution layer;
a first substrate disposed on the redistribution layer and having a first cavity;
a first semiconductor chip at least partially disposed in the first cavity and having a first connection pad disposed to face the redistribution layer;
a first encapsulant disposed between the redistribution layer and the first substrate, covering at least a portion of the first semiconductor chip, and filling at least a portion of the first cavity;
a second substrate disposed on the first substrate and having a second cavity;
a second semiconductor chip at least partially disposed in the second cavity and having a second connection pad disposed to face the first substrate;
a second encapsulant disposed between the first and second substrates, covering at least a portion of the second semiconductor chip, and filling at least a portion of the second cavity;
a first connection via penetrating through the first encapsulant, directly connected to the first connection pad, and connecting the first connection pad to the redistribution layer; and
a second connection via penetrating through the first substrate and the first and second encapsulants, directly connected to the second connection pad, and connecting the second connection pad to the redistribution layer.

2. The semiconductor package of claim 1, wherein the first and second semiconductor chips are each a memory die.

3. The semiconductor package of claim 1, wherein the first and second substrates are each an organic substrate, and the organic substrate includes a copper clad laminate (CCL) or an unclad CCL.

4. The semiconductor package of claim 1, wherein each of the first and second connection vias is tapered so that a width of an end portion thereof connected to the redistribution layer in a cross-section is wider than a width of an end portion connected to the first or second connection pad, respectively.

5. The semiconductor package of claim 1, wherein the first and second cavities are through-cavities penetrating between opposing one surface and the other surface of each of the first and second substrates, respectively.

6. The semiconductor package of claim 1, wherein a surface of the first substrate in contact with the second encapsulant is substantially coplanar with a surface of the first semiconductor chip in contact with the second encapsulant.

7. The semiconductor package of claim 1, further comprising:
a third substrate disposed on the second substrate and having a third cavity;
a third semiconductor chip at least partially disposed in the third cavity and having a third connection pad disposed to face the second substrate;
a third encapsulant disposed between the second and third substrates, covering at least a portion of the third semiconductor chip, and filling at least a portion of the third cavity; and
a third connection via penetrating through the first and second substrates and the first to third encapsulant, directly connected to the third connection pad, and connecting the third connection pad to the redistribution layer.

8. The semiconductor package of claim 7, wherein the third connection via includes a 3-1 connection via penetrating through the second substrate and the second and third encapsulants and directly connected to the third connection pad and a 3-2 connection via penetrating through the first substrate and the first encapsulant and connecting the 3-1 connection via to the redistribution layer.

9. The semiconductor package of claim 8, wherein, in a cross-section, a width of an end portion of the 3-1 connection via connected to the 3-2 connection via is wider than a width of an end portion of the 3-2 connection via connected to the 3-1 connection via.

10. The semiconductor package of claim 7, further comprising:
a fourth substrate disposed on the third substrate and having a fourth cavity;
a fourth semiconductor chip at least partially disposed in the fourth cavity and having a fourth connection pad disposed to face the third substrate;
a fourth encapsulant disposed between the third and fourth substrates, covering at least a portion of the fourth semiconductor chip, and filling at least a portion of the fourth cavity; and
a fourth connection via penetrating through the first to third substrates and the first to fourth encapsulant, directly connected to the fourth connection pad, and connecting the fourth connection pad to the redistribution layer.

11. The semiconductor package of claim 10, wherein the fourth connection via includes a 4-1 connection via penetrating through the third substrate and the third and fourth encapsulants and directly connected to the fourth connection pad, a 4-2 connection via penetrating through the second substrate and the second encapsulant and connected to the 4-1 connection via, and a 4-3 connection via penetrating through the first substrate and the first encapsulant and connecting the 4-2 connection via to the redistribution layer.

12. The semiconductor package of claim 11, wherein, in a cross-section, a width of an end portion of the 4-1 connection via connected to the 4-2 connection via is wider than a width of an end portion of the 4-2 connection via connected to the 4-1 connection via, and a width of an end portion of the 4-2 connection via connected to the 4-3 connection via is wider than a width of an end portion of the 4-3 connection via connected to the 4-2 connection via.

13. The semiconductor package of claim 1, wherein the redistribution layer includes a plurality of insulating layers, a plurality of conductive pattern layers respectively disposed within the plurality of insulating layers, and a plurality of conductive via layers respectively disposed within the plurality of insulating layers and respectively connected to at least one of the plurality of conductive pattern layers.

14. The semiconductor package of claim 1, further comprising:
a plurality of electrical connection metals, each of which is disposed on a side of the redistribution layer opposite to a side on which the first substrate is disposed; and
a chip package including a system on chip (SoC),
wherein the redistribution layer is disposed on the chip package and is connected to the chip package through the plurality of electrical connection metals.

15. A semiconductor package comprising:
a redistribution layer;
a plurality of encapsulants and a plurality of substrates alternately arranged on the redistribution layer;
a plurality of memory dies at least partially disposed in cavities penetrating each of the plurality of substrates and at least partially covered by the plurality of encapsulants, respectively; and
a plurality of connection vias penetrating at least one of the plurality of encapsulants and the plurality of substrates and solderlessly connected to the plurality of memory dies, respectively, and connecting each of the plurality of memory dies to the redistribution layer.

16. The semiconductor package of claim 15, wherein the plurality of connection vias have different heights.

17. A semiconductor package comprising:
a redistribution layer; and
a stack of layer structures disposed on the redistribution layer, wherein each respective layer structure in the stack of layer structures comprises:
a corresponding substrate having (i) a corresponding first surface facing the redistribution layer and (ii) a corresponding second surface opposite to the corresponding first surface;
a corresponding cavity disposed in the corresponding substrate and penetrating at least the corresponding first surface of the corresponding substrate;
a corresponding semiconductor chip at least partially disposed in the corresponding cavity, the corresponding semiconductor chip having (i) a corresponding front surface facing the redistribution layer and (ii) a corresponding connection pad facing the redistribution layer and electrically connected to the redistribution layer; and
a corresponding encapsulant having (i) a first portion filling a portion of the corresponding cavity and (ii) a second portion covering the corresponding front surface of the corresponding semiconductor chip, the corresponding first surface of the corresponding substrate, and one of the redistribution layer and a second surface of a substrate of an adjacent layer structure in the stack of layer structures.

18. The semiconductor package of claim 17, wherein
the stack of layer structures comprises two, three, four or more than four layer structures.

19. The semiconductor package of claim 17, wherein
the corresponding substrate is an organic substrate.

20. The semiconductor package of claim 17, wherein
the corresponding cavity penetrates both of the corresponding first surface and
the corresponding second surface of the corresponding substrate.

21. The semiconductor package of claim 17, wherein
the corresponding connection pad of the corresponding semiconductor chip is electrically connected to the redistribution layer by one or more corresponding connection vias penetrating any encapsulant and any substrate between the corresponding connection pad and the redistribution layer.

22. The semiconductor package of claim 21, wherein
each of the one or more corresponding connection vias is tapered along a direction substantially perpendicular to the redistribution layer such that an end thereof facing the redistribution layer is wider than an end thereof facing away from the redistribution layer.

23. The semiconductor package of claim 17, wherein
the corresponding semiconductor chip is a memory die.

24. The semiconductor package of claim 17, wherein
the first portion of the corresponding encapsulant surrounds circumferentially the corresponding semiconductor chip.

25. The semiconductor package of claim 17, wherein
the redistribution layer is disposed on a chip package and connected to the chip package through a plurality of electrical connection metals.
